(19) United States
(12) Patent Application Publication
(10) Pub. No.: US 2003/0216043 A1
(43) Pub. Date: Nov. 20, 2003

(54) Method for producing a device having a semiconductor layer on a lattice mismatched substrate

(76) Inventors: Giovanni Flamand, Wijnegem (BE); Jef Poortmans, Kessel-Lo (BE)

Correspondence Address: KNOBBE MARTENS OLSON & BEAR LLP, 2040 MAIN STREET, FOURTEENTH FLOOR, IRVINE, CA, 92614, US

(21) Appl. No.: 10/377,292

(22) Filed: Feb. 27, 2003

Related U.S. Application Data
(60) Provisional application No. 60/367,026, filed on Mar. 22, 2002.

(30) Foreign Application Priority Data
Feb. 28, 2002 (EP) 02447031.2

(51) Int. Cl. H01L 21/302; H01L 21/461

(52) U.S. Cl. 438/689

(57) ABSTRACT

The present invention relates to a layer stack comprising a monocrystalline layer located upon a porous surface of a substrate, said monocrystalline layer and said substrate being significantly lattice mismatched, obtainable by a process comprising a sublimation or an evaporation step by emission from a source and an incomplete filling step of said porous surface by said sublimated or evaporated emission.

### RELATED APPLICATION

This application claims the benefit of U.S. Provisional Application No. 60/367,026, filed Mar. 22, 2002.

### FIELD OF THE INVENTION

The present invention relates to a dislocation-free monocrystalline (epitaxial layer) on a substrate when a significant lattice mismatch exists between the substrate and the monocrystalline layer. The present invention equally relates to a method for growing the dislocation-free monocrystalline layer on top of the substrate.

### BACKGROUND OF THE INVENTION

In a large variety of semiconductor devices, it is desirable to have a monocrystalline layer sequence of lattice mismatched materials. For example, the hetero-epitaxial growth of different types of semiconductor film such as Ge, GeₓSi₁₋ₓ or Group IIIV semiconductors such as GaAs on a Si substrate can allow the monolithic integration of special function devices, e.g., optical detectors, laser, light-emitting diodes (LEDs) or high speed transistors with Si ultra large scale integrated circuits. Alternatively, the epitaxial growth of high band gap semiconductors on the most common substrates such as Si can lead to a cheaper, high volume process for the manufacture of short wavelength diode lasers (yellow, green, blue, and ultraviolet) or multi-junction monolithic cascade solar cells.

For many years attempts have been made to grow various epitaxial layers on significantly lattice mismatched substrates by conventional techniques such as chemical vapor deposition (CVD) or molecular beam epitaxy (MBE). By ‘significantly lattice mismatched’ it is meant that the substrate and the epitaxial layer differ in their lattice constants by at least 0.3%, preferably 0.5% or more. As used herein, the words ‘epitaxial’ and ‘monocrystalline’ are synonyms.

In the case of CVD, it is not easy to achieve high conversion efficiency from gaseous precursors to the desired semiconductor layer on the substrate without negatively affecting uniformity. In the case of MBE, the yield is higher but the complexity of the associated equipment is large. The resulting epitaxial layers always contain a large number of defects because of the difference in lattice constant and thermal expansion coefficient between the host substrate and the grown crystal.

U.S. Pat. Nos. 4,806,996 and 5,981,400 describe a method for overcoming significant lattice mismatches, which consists of making the base material porous at the top surface or in patterning the top surface of the base layer before growing the other material by conventional techniques.

M. T. Currie et al. in App. Phys. Lett., volume 72, number 14, page 1718, describes a method to grow epitaxial Ge on Si which uses a graded Si/Ge buffer layer deposited by ultra high vacuum chemical vapor deposition (UHVCVD). However, the method is complex and expensive.

### SUMMARY OF THE INVENTION

The fact that no commercial devices have appeared on the market gives an indication that none of the methods described in the prior art leads to the growth of high quality layers with high degrees of crystallinity. It is known that the desirable properties of a layer are usually enhanced by the degree of crystallinity of the layer itself. For instance, the electron mobility and the band gap value are directly related to the crystallinity of the semiconductor layer. Therefore, the high quality of the grown crystal is a fundamental requirement for fabricating working devices.

A device comprising a dislocation-free monocrystalline layer on a substrate, wherein a significant lattice mismatch exists between the substrate and the monocrystalline layer, is therefore desirable.

Accordingly, the preferred embodiments are related to a method for producing a device in the form of a layer stack comprising a dislocation-free monocrystalline layer located upon the porous surface of a substrate, the monocrystalline layer and the substrate being significantly lattice mismatched. ‘Significantly lattice mismatched’ as used herein means a difference in lattice constants between the substrate and the monocrystalline layer of generally between about 0.5 and 10%, preferably between about 0.5 and 8%, more preferably between about 1 and 6%, and most preferably about 4%. In particular, the method comprises a step of growing the dislocation-free monocrystalline layer. In particular the method comprises a step of growing the dislocation free monocrystalline layer. Before the step, a sublimation step or an evaporation step of material from a source is performed and an incomplete or partial filling of the porous surface of the substrate by the sublimated or evaporated material is obtained. The sublimation or evaporation step and the filling step are accompanied by a chemical reaction of the material form the source. In a first step, the source material is oxidized and in a second step, the oxidized material is reduced while being deposited into the pores of the substrate.

Compared to MBE, the method of the preferred embodiments allows higher deposition rates. Moreover, the method of the preferred embodiments does not have to be performed at high vacuum, which requires complicated equipment. Consequently, the method of the preferred embodiments is cheaper.

The preferred embodiments are also related to a device in the form of a layer stack comprising a dislocation-free monocrystalline layer located upon the porous top surface of a substrate, the monocrystalline layer and the substrate being significantly lattice mismatched, wherein the porous surface is partially filled with sublimated or evaporated material, the device being obtainable by the method described above.

In a preferred embodiment, the dislocation free monocrystalline layer located on the porous surface of the substrate is obtained by a close space vapor transport (CSVT) process.

In another preferred embodiment is provided a method for producing a free standing device in the form of a layer stack, comprising a dislocation-free monocrystalline layer located upon a porous surface of a substrate, the monocrystalline layer and the substrate being significantly lattice mismatched. Before the step, a sublimation step or an evaporation step of material from a source is performed and an incomplete or partial filling of the porous surface of the substrate by the sublimated or the evaporated material is obtained.

The preferred embodiments are also related to the free standing device in the form of a layer stack comprising a dislocation-free monocrystalline layer located upon a porous surface of a substrate, the monocrystalline layer and the substrate being significantly lattice mismatched, wherein the porous surface is partially filled with sublimated or evaporated material, the device being obtainable by the method described above. The device obtained by the method described above can be made free standing from the substrate by a lift-off process. By ‘free standing’ it is understood to refer to a device that is able to support itself after being subjected to a deformation.

In a preferred embodiment, the dislocation free monocrystalline layer located on the porous surface of the substrate is obtained by close space vapor transport (CSVT) process.

Preferably, the monocrystalline layer is essentially germanium and the substrate is essentially silicon.

The devices in the form of layer stacks described above can be used for semiconductor applications such as optical detectors, lasers, light-emitting diodes, and high-speed transistors.

In a first embodiment, a device comprising a layer stack is provided, the layer stack comprising a substantially dislocation-free monocrystalline layer atop a porous surface of a substrate, wherein a difference in lattice constants between the substrate and the monocrystalline layer is greater than or equal to 0.3%, wherein the monocrystalline layer comprises germanium, wherein the substrate comprises silicon, wherein the porous surface comprises a plurality of pores, wherein the porous surface has a pore volume greater than or equal to about 10 vol. %, wherein the pores are partially filled with a material, wherein the material comprises germanium, and wherein a plurality of voids are situated between the monocrystalline layer and the substrate.

In an aspect of the first embodiment, the difference in lattice constants between the substrate and the monocrystalline layer is greater than or equal to 0.5%.

In an aspect of the first embodiment, the difference in lattice constants between the substrate and the monocrystalline layer is greater than or equal to 1%.

In an aspect of the first embodiment, the difference in lattice constants between the substrate and the monocrystalline layer is greater than or equal to 4%.

In an aspect of the first embodiment, the pore volume is from about 10 vol. % to about 80 vol.

In an aspect of the first embodiment, the pore volume is from about 20 vol. % to about 70 vol. %.

In an aspect of the first embodiment, the device is an optical detector.

In an aspect of the first embodiment, the device is a laser.

In an aspect of the first embodiment, the device is light-emitting diode.

In an aspect of the first embodiment, the device is high-speed transistor.

In a second embodiment, a method for fabricating a free standing device comprising a layer stack is provided, the method comprising the steps of providing a substrate, the substrate comprising a porous surface, the porous surface comprising a plurality of pores; sublimating or evaporating a material; depositing the sublimated or evaporated material in the pores of the porous surface, whereby the pores are partially filled with the material; and growing a substantially dislocation-free monocrystalline layer on the substrate, wherein the substrate and the monocrystalline layer are significantly lattice mismatched, thereby obtaining a layer stack.

In an aspect of the second embodiment, the monocrystalline layer comprises germanium and the substrate comprises silicon.

In an aspect of the second embodiment, the material comprises germanium.

In an aspect of the second embodiment, the step of growing a substantially dislocation-free monocrystalline layer comprises a close space vapor transport process.

In a third embodiment, a method for producing a device is provided, the device comprising a dislocation-free monocrystalline layer situated atop a porous surface of a substrate, the monocrystalline layer and the substrate being significantly lattice mismatched, the method comprising the steps of providing a substrate, the substrate comprising a porous layer at a surface of the substrate, the porous later comprising a plurality of pores; sublimating or evaporating a material from a source, whereby the material is oxidized to yield an oxidized source material; and depositing the oxidized source material in the pores, whereby the oxidized source material is reduced.

In an aspect of the third embodiment, the pores are at least partially filled.

In an aspect of the third embodiment, the pores are incompletely filled.

In an aspect of the third embodiment, the method further comprises the step of growing a substantially dislocation-free monocrystalline layer on the substrate, wherein the step is conducted after the step of depositing the oxidized source material in the pores, whereby a layer stack is obtained. The step of growing a substantially dislocation-free monocrystalline layer on the substrate can comprise a close space vapor transport process.

In an aspect of the third embodiment, a distance between the source and the porous layer at the surface of the substrate is from about 0.01 cm to about 1 cm.

In an aspect of the third embodiment, the step of sublimating or evaporating is performed at a pressure greater than or equal to 10⁻³ atmospheres.

In an aspect of the third embodiment, the temperature of the source is higher than the temperature of the substrate.

In an aspect of the third embodiment, the method further comprises the step of lifting the layer stack from the substrate.

In an aspect of the third embodiment, the source material comprises germanium and the substrate comprises silicon.

### BRIEF DESCRIPTION OF THE DRAWINGS

The preferred embodiments will be described in more detail with reference to the attached drawings.

FIG. 1 represents the schematic set-up used for the deposition of epitaxial Ge onto a porous surface of a Si wafer according to a preferred embodiment.

FIG. 2 represents the Si porous surface partially filled with sublimated or evaporated Ge.

FIG. 3 represents the schematic set-up used for the deposition of epitaxial Ge onto a porous surface of a Si wafer according to a preferred embodiment.

FIG. 4 represents the X-Ray Diffraction (XRD) pattern of epitaxial Ge layer grown onto a porous surface of a Si wafer.

FIG. 5 represents the schematic set-up used for the deposition of epitaxial Ge onto a porous surface of a Si wafer according to a preferred embodiment.

### DETAILED DESCRIPTION OF THE PREFERRED EMBODIMENT

The following description and examples illustrate a preferred embodiment of the present invention in detail. Those of skill in the art will recognize that there are numerous variations and modifications of this invention that are encompassed by its scope. Accordingly, the description of a preferred embodiment should not be deemed to limit the scope of the present invention.

The preferred embodiments are related to a method for producing a device in the form of a layer stack comprising a dislocation-free monocrystalline layer located upon the porous surface of a substrate, the monocrystalline layer and the substrate being significantly lattice mismatched. The porous layer can have a porosity profile of the type lower/higher/lower or higher/lower and the porosity typically varies from about 10 vol. % to about 80 vol. %, preferably from about 20 vol. % to about 70 vol. %. The thickness of the porous layer generally ranges from about 20 nm to about 50 μm, preferably from about 100 nm to about 50 μm, more preferably from about 1 μm to about 50 μm, and most preferably from about 5 μm to about 20 μm. ‘Significantly lattice mismatched’ as used herein refers to a difference in lattice constants between the substrate and the monocrystalline layer generally of from about 0.5% to about 10%, preferably from about 0.5% to about 8%, more preferably from about 1% to about 6%, and most preferably about 4%. In particular, the method comprises a step of growing the dislocation-free monocrystalline layer. In particular, the method comprises a step of growing the dislocation free monocrystalline layer. Before the step a sublimation step or an evaporation step of material from a source is performed and an incomplete or partial filling of the porous surface of the substrate by the sublimated or evaporated material is obtained. The sublimation or evaporation step and the filling step are accompanied by a chemical reaction of the material form the source. In a first step, the source material is oxidized and in a second step, the oxidized material is reduced while being deposited into the pores of the substrate. The sublimation and evaporation steps are performed in an atmosphere comprising an oxidizing agent such as, e.g., water vapor or the like. The chemical reaction between the source X and the oxidizing agent is as follows:

X+H₂O→X-oxide+H₂

This reaction is driven by the temperature, with a higher temperature forcing the reaction to the oxidized form of the source material. The preferred temperature of the source material depends on the characteristics of the source material. The temperature is preferably such that an evaporation or sublimation of the source material occurs.

In a second step, the oxidized source material is reduced while being deposited on the porous substrate such that a monocrystalline layer is formed. The monocrystalline layer comprises at least the source material. The reduction reaction is as follows:

X-oxide→X

The oxidation and reduction reactions are driven by the temperature difference between the source material and the porous substrate. The source material is preferably at a higher temperature than the porous substrate. The temperature difference between the source material and the porous substrate is generally from about 10° C. to about 150° C., preferably from about 20° C. to about 150° C., more preferably from about 20° C. to about 100° C., even more preferably from about 40° C. to about 70° C., and most preferably about 50 or 60° C.

The distance between the source material and the porous substrate is generally from about 0.01 cm to about 1 cm, preferably from about 0.01 m to about 0.5 cm, more preferably from about 0.01 cm to about 0.1 cm, and most preferably about 0.2 cm, 0.3 cm, 0.1 cm, or 0.05 cm.

The method is generally performed at a pressure of from about 10-3 atm to about 1 atm, preferably from about 10-2 atm to about 1 atm, more preferably from about 10-I atm to about 1 atm, and most preferably from about 0.2 atm to about 1 atm. Particularly preferred pressures include about 0.4 atm, 0.5 atm, and 0.6 atm. Compared to MBE, which requires a very high vacuum, the method of the preferred embodiments is performed at a higher pressure.

The monocrystalline layer comprises the source material. The source material can be any semiconducting material. The semiconducting material can be a group III material, a group IV material, or a group V material. The source material can comprise a material selected from the group including Si, Ge, Ga, As, In, Se, Cu, Al, Tl, Sn, Pb, B, P, Sb, Bi and compounds thereof. Preferably, the source material is germanium. Preferably, the monocrystalline layer consists essentially of germanium. The substrate is a substrate having pores. The substrate can be made of a semiconducting material. The semiconducting material can be an inorganic semiconducting material or an organic semiconducting material. Preferably, the substrate consists essentially of silicon.

The porous layer can have a porosity profile of the type lower/higher/lower or higher/lower and the porosity can vary between 20 vol. % and 70 vol. %. The thickness of the porous layer is generally higher than about 50 nm, preferably higher than about 100 nm, and most preferably higher than about 1 μm. The thickness is generally from about 100 nm to about 50 μm, preferably from about 100 nm to about 20 μm, and most preferably from about 1 μm to about 10 μm. Particularly preferred thicknesses include about 2 μm, about 3 μm, and about 4 μm.

The resulting monocrystalline layer preferably has a thickness sufficient to allow polishing of the layer. The thickness is preferably from about 1 μm to about 50 μm, most preferably from about 5 μm to about 20 μm.

In an aspect of the preferred embodiments, a dislocation-free monocrystalline layer is grown onto a significantly lattice mismatched substrate by the methods illustrated in the following embodiments.

In a first embodiment, a dislocation-free epitaxial Ge layer is grown onto the top surface of a Si substrate. A lattice mismatch of about 4% exists between the Si substrate and the Ge layer. Therefore, a porous layer is first formed at the surface of the Si substrate. The step of forming a porous layer can be done by an anodization technique or according to any other method known by a person skilled in the art. The porous layer can have a porosity profile of the type lower/higher/lower or higher/lower and the porosity can vary between 20 and 70 vol. %. The thickness of the porous layer is preferably greater than about 50 nm, more preferably greater than about 100 nm, and most preferably greater than about 1 μm. The thickness is generally from about 100 nm to about 50 μm, preferably from about 100 nm to about 20 μm, and more preferably from about 1 μm to about 10 μm. Most preferably, the thickness is about 2 μm, about 3 μm, or about 4 μm.

The Ge material is then sublimated from a Ge source. The Germanium source can be in the solid phase or can be in the liquid phase.

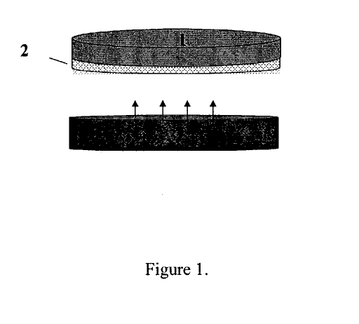

FIG. 1 illustrates the schematic experimental set-up employed in the first embodiment.

A wafer comprising a Si substrate (1) having a porous Si layer (2) is placed in the set-up and a Ge wafer (3) serves as a Ge source for the sublimated or evaporated material.

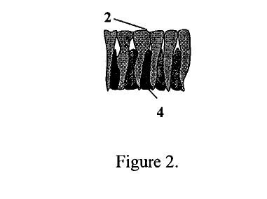

Both wafers are placed opposite each other, separated by a spacer only a few hundred μm thick (not shown). When the system is brought to a temperature of from about 700 to about 930° C. under an H₂-atmosphere, sublimation of Ge occurs. The Si pores start to fill with sublimated Ge material (4). The filling is a function of time. After one hour, for example, Si pores are filled with Ge to a depth of about 600 nm. According to Rutherford Backscattering (RBS) analysis, 30% Ge is present at the Si/porous Si substrate when the surface porosity is about 30%, and the Ge content linearly decreases over the depth. An empty space is still present underneath such a Si/Ge graded layer as shown in FIG. 2.

In a second embodiment, a dislocation free epitaxial Ge layer is grown onto a Si substrate by forming a porous layer at the surface of the Si substrate as described in the first embodiment, followed by the sublimation of Ge onto the porous Si at a temperature of from about 950° C. to about 1000° C. under an H₂-atmosphere.

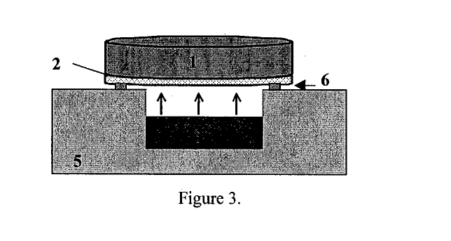

In this case, the Si (1)/porous Si (2) wafer is placed over a graphite susceptor (5) and separated from it by thin spacers (6) as shown in FIG. 3.

The first wafer consists of a Si substrate (1) on which a porous Si layer (2) is created. A second wafer, which is a bulk Ge wafer (3) is placed as a source of evaporated material in a cavity of the graphite susceptor. At 936° C., Ge melts, starts to evaporate, and diffuses into the pores in the Si wafer. The distance between the bulk Ge wafer and the Si wafer is approximately 1 cm. The Si pores start filling with evaporated Ge (4) and the filling is a function of time. For example, after one hour Si pores are filled with Ge to a depth of about 600 nm. According to RBS analysis, 30% Ge is present at the Si/porous Si substrate when the surface porosity is about 30%, and the Ge content linearly decreases over the depth. An empty space is present underneath such a Si/Ge graded layer as shown in FIG. 2.

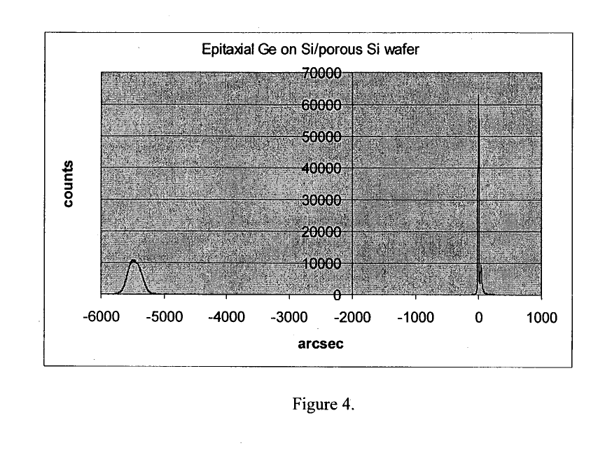

In both the first and second embodiments, dislocation-free epitaxial Ge is grown to the desired thickness on top of the graded Si/Ge layer by a plasma enhanced CVD technique. The fact that the Ge is epitaxial is evidenced by the XRD analysis shown in FIG. 4. At zero arcsec, two peaks are observed, one from the Si-wafer and one from the porous Si layer. At −5500 arcsec there is a peak belonging to the Ge layer grown on top. Any other growth technique such as UHCVD, metal organic chemical vapor deposition (MOCVD), MBE, can be successfully employed to grow epitaxial Ge after the formation of the Si/Ge graded layer by sublimation. In fact, the stress related to the growth of epitaxial Ge is largely relieved by the presence of empty pores underneath the Si/Ge graded layer.

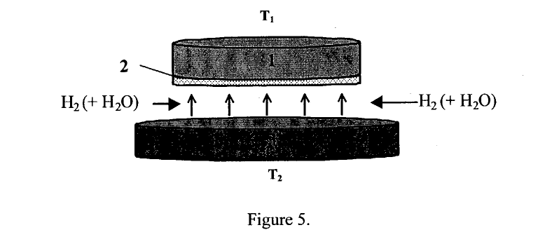

In a third embodiment, a porous layer is first formed at the surface of the Si substrate as described in the first embodiment. Dislocation-free epitaxial Ge of the desired thickness is then grown in one step by a close space vapor transport (CSVT) process on the wafer comprising a Si substrate (1) on which porous Si (2) layer as schematically shown in FIG. 5.

The CSVT technique relies on the temperature difference between the sublimation source and the receiving substrate. In the preferred embodiments, the Ge source (3) is placed at a distance of a few tenths of a mm from the Si (1)/porous Si (2) wafer. The temperature (T₁) of the Si/porous Si substrate is kept hundreds of degrees lower that the temperature (T₂) of the Ge source. The experiments are performed in H₂ atmosphere, with the addition of water vapor. When T₂ is high enough at the desired pressure, Ge starts to sublimate Ge (4) first diffuses into the Si pores of the Si (1)/porous Si (2) substrate, then after that epitaxial Ge starts to grow on top of the Si/Ge graded layer.

In spite of the fact that CSVT process is not recognized as a conventional technique by the IC world, it has a lot of advantages. CSVT has a high yield, is relatively simple if compared to CVD or MBE techniques, and does not require vacuum. In addition, the CSVT process can be applied on a large scale and is therefore suitable for industrial use.

According to another aspect of the preferred embodiment, a device in the form of layer stack comprising a dislocation-free monocrystalline layer situated atop a porous surface of a substrate is obtained, the monocrystalline layer and the substrate being significantly lattice mismatched. Such a device is advantageously obtained by the CSVT technique or by any of the techniques described above, which in the first instance fill the pores of the porous Si by sublimation or evaporation of material from a source.

Preferably, the substrate is Si because it is available in large sizes (>8 inch) with a high degree of crystallinity (very low defect density<1 cm⁻²) and mechanical perfection. Moreover, it features a high mechanical strength and a thermal conductivity several times higher than many other semiconductors. However, other semiconductor substrates can also be employed, as are known by those of skill in the art. Analogously, materials other than Ge, selected from the group III-V semiconductors, such as GaAs, can be grown as dislocation-free monocrystalline layers on a Si substrate.

An additional aspect of the preferred embodiments provides a freestanding device in the form of a layer stack made of a dislocation-free monocrystalline layer on a porous carrier. The free standing layer stack can be obtained by a lift-off process. For example, the graded Si/Ge layer formed at the interface between porous Si and Ge, according to the previous embodiments described above, can be lifted off from the Si-substrate to yield a free-standing Ge film partially filled Si carrier. The Si carrier provides mechanical strength for the Ge film and acts as a complying substrate for the Ge film, resulting in a material with lower defect density. The lift-off of the Si/Ge layer can be done either mechanically or by wet chemistry, or even spontaneously if the porosity profile in partially filled Si layer is large enough.

This proves that this technique can be used to produce free-standing, porous Si/Ge templates (5) as illustrated in FIG. 5.

The production of dislocation-free Ge epitaxial layers on a Si substrate can serve as starting platforms for the growth of GaAs and/or AlGaAs for the production of reliable, low-cost GaAs-based optical, electronic, or optoelectronic devices and can pave the way to monolithic integration of silicon and compound semiconductor devices.

The above description discloses several methods and materials of the present invention. This invention is susceptible to modifications in the methods and materials, as well as alterations in the fabrication methods and equipment. Such modifications will become apparent to those skilled in the art from a consideration of this disclosure or practice of the invention disclosed herein. Consequently, it is not intended that this invention be limited to the specific embodiments disclosed herein, but that it cover all modifications and alternatives coming within the true scope and spirit of the invention as embodied in the attached claims. All patents, applications, and other references cited herein are hereby incorporated by reference in their entirety.

What is claimed is:

1. A device comprising a layer stack, the layer stack comprising a substantially dislocation-free monocrystalline layer atop a porous surface of a substrate, wherein a difference in lattice constants between the substrate and the monocrystalline layer is greater than or equal to 0.3%, wherein the monocrystalline layer comprises germanium, wherein the substrate comprises silicon, wherein the porous surface comprises a plurality of pores, wherein the porous surface has a pore volume greater than or equal to about 10 vol. %, wherein the pores are partially filled with a material, wherein the material comprises germanium, and wherein a plurality of voids are situated between the monocrystalline layer and the substrate.

2. The device of claim 1, wherein the difference in lattice constants between the substrate and the monocrystalline layer is greater than or equal to 0.5%.

3. The device of claim 1, wherein the difference in lattice constants between the substrate and the monocrystalline layer is greater than or equal to 1%.

4. The device of claim 1, wherein the difference in lattice constants between the substrate and the monocrystalline layer is greater than or equal to 4%.

5. The device of claim 1, wherein the pore volume is from about 10 vol. % to about 80 vol. %.

6. The device of claim 1, wherein the pore volume is from about 20 vol. % to about 70 vol. %.

7. The device of claim 1, comprising an optical detector.

8. The device of claim 1, comprising a laser.

9. The device of claim 1, comprising a light-emitting diode.

10. The device of claim 1, comprising a high-speed transistor.

11. A method for fabricating a free standing device comprising a layer stack, the method comprising the steps of:
providing a substrate, the substrate comprising a porous surface, the porous surface comprising a plurality of pores;
sublimating or evaporating a material;
depositing the sublimated or evaporated material in the pores of the porous surface, whereby the pores are partially filled with the material; and
growing a substantially dislocation-free monocrystalline layer on the substrate, wherein the substrate and the monocrystalline layer are significantly lattice mismatched, thereby obtaining a layer stack.

12. The method of claim 11, wherein the monocrystalline layer comprises germanium and the substrate comprises silicon.

13. The method of claim 11, wherein the material comprises germanium.

14. The method of claim 11, wherein the step of growing a substantially dislocation-free monocrystalline layer comprises a close space vapor transport process.

15. A method for producing a device, the device comprising a dislocation-free monocrystalline layer situated atop a porous surface of a substrate, the monocrystalline layer and the substrate being significantly lattice mismatched, the method comprising the steps of:
providing a substrate, the substrate comprising a porous layer at a surface of the substrate, the porous later comprising a plurality of pores;
sublimating or evaporating a material from a source, whereby the material is oxidized to yield an oxidized source material; and
depositing the oxidized source material in the pores, whereby the oxidized source material is reduced.

16. The method as in claim 15, wherein the pores are at least partially filled.

17. The method of claim 15, wherein the pores are incompletely filled.

18. The method of claim 15, further comprising the step of growing a substantially dislocation-free monocrystalline layer on the substrate, wherein the step is conducted after the step of depositing the oxidized source material in the pores, whereby a layer stack is obtained.

19. The method of claim 15, wherein a distance between the source and the porous layer at the surface of the substrate is from about 0.01 cm to about 1 cm.

20. The method of claim 15, wherein the step of sublimating or evaporating is performed at a pressure greater than or equal to 10⁻³ atmospheres.

21. The method of claim 15, wherein the temperature of the source is higher than the temperature of the substrate.

22. The method of claim 18, the wherein the step of growing a substantially dislocation-free monocrystalline layer on the substrate comprises a close space vapor transport process.

23. The method of claim 18, further comprising the step of lifting the layer stack from the substrate.

24. The method of claim 15, wherein the source material comprises germanium and the substrate comprises silicon.
